(19) United States
(12) Patent Application Publication
(10) Pub. No.: US 2009/0155580 A1
(43) Pub. Date: Jun. 18, 2009

(54) Production Methods of Semiconductor Crystal and Semiconductor Substrate

(76) Inventors: Naoki Shibata, Aichi (JP); Koji Hirata, Aichi (JP); Shiro Yamazaki, Aichi (JP); Katsuhiro Imai, Aichi (JP); Makoto Iwai, Aichi (JP); Takatomo Sasaki, Osaka (JP); Yusuke Mori, Osaka (JP); Fumio Kawamura, Osaka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/225,389

(22) PCT Filed: Apr. 5, 2007
(86) PCT No.: PCT/JP2007/058025

§ 371 Date: Jan. 23, 2009

(30) Foreign Application Priority Data
Apr. 7, 2006 (JP) 2006-106720

(51) Int. Cl. C30B 19/02; B32B 9/00; B32B 1/00

(52) U.S. Cl. 428/336; 117/56; 117/58; 117/64; 428/337

(57) ABSTRACT

To provide a semiconductor substrate of high quality suitable for fabricating an electronic device or an optical device. The present invention provides a method for producing a semiconductor substrate for an electronic device or an optical device, the method including reacting nitrogen (N) with gallium (Ga), aluminum (Al), or indium (In), which are group III elements, in a flux mixture containing a plurality of metal elements selected from among alkali metals and alkaline earth metals, to thereby grow a group III nitride based compound semiconductor crystal. The group III nitride based compound semiconductor crystal is grown while the flux mixture and the group III element are mixed under stirring. At least a portion of a base substrate on which the group III nitride based compound semiconductor crystal is grown is formed of a flux-soluble material, and the flux-soluble material is dissolved in the flux mixture, at a temperature near the growth temperature of the group III nitride based compound semiconductor crystal, during the course of growth of the semiconductor crystal or after completion of growth of the semiconductor crystal.

### TECHNICAL FIELD

The present invention relates to a flux method for producing a group III nitride based compound semiconductor by using a flux and a semiconductor substrate produced by the flux method.

### BACKGROUND ART

Conventionally employed sodium (Na) flux processes, which grow gallium nitride crystal in an Na flux, can grow a GaN single crystal at a pressure of about 5 MPa and at a relatively low temperature of 600° C. to 800° C.

As disclosed in, for example, the below-described Patent Documents 1 to 5, in conventional methods for producing a group III nitride based compound semiconductor crystal, the crystal is grown through the flux process. Such a conventional production method generally employs, as a base substrate (seed crystal), a template formed by successively providing, on a sapphire substrate, a buffer layer and a semiconductor layer (e.g., a single-crystal GaN layer); a GaN single-crystal self-standing substrate; or a similar substrate.

[Patent Document 1] Japanese Patent Application Laid-Open (kokai) No. H11-060394

[Patent Document 2] Japanese Patent Application Laid-Open (kokai) No. 2001-058900

[Patent Document 3] Japanese Patent Application Laid-Open (kokai) No. 2001-064097

[Patent Document 4] Japanese Patent Application Laid-Open (kokai) No. 2004-292286

[Patent Document 5] Japanese Patent Application Laid-Open (kokai) No. 2004-300024

### DISCLOSURE OF THE INVENTION

### Problems to be Solved by the Invention

However, conventional Na flux processes encounter difficulty in producing a transparent semiconductor crystal of high quality having low dislocation density and an almost flat crystal growth surface. In addition, the conventional Na flux processes pose problems in terms of crystal growth rate and yield, and therefore difficulty is encountered in applying the flux processes to production of a semiconductor substrate (e.g., a semiconductor substrate for electronic devices, or an optical device semiconductor substrate). Such problems also arise in the case of growth of a group III nitride based compound semiconductor crystal formed of InₓAl_{y}Ga_{1-x-y}N (0≦x≦1, 0≦y≦1, 0≦x+y≦1).

In the case where the aforementioned template is employed as a base substrate, when a target group III nitride based compound semiconductor crystal is grown on the base substrate so as to have a large thickness, a large number of cracks are generated in the semiconductor crystal during removal of the semiconductor crystal from a reaction chamber, because of a greater difference in thermal expansion coefficient between the semiconductor crystal and the sapphire substrate. Therefore, in this case, difficulty is encountered in producing, for example, a semiconductor crystal of high quality having a thickness of 400 μm or more.

The present invention has been accomplished in order to solve the aforementioned problems. An object of the present invention is to produce, through the flux process at low cost, a semiconductor crystal of high quality.

### Means for Solving the Problems

The aforementioned problems are effectively solved by techniques falling under the below-described aspects.

In a first aspect of the present invention, there is provided a method for producing a semiconductor crystal, the method comprising reacting nitrogen (N) with gallium (Ga), aluminum (Al), or indium (In), which are group III elements, in a flux mixture containing a plurality of metal elements selected from among alkali metals and alkaline earth metals, to thereby grow a group III nitride based compound semiconductor crystal, wherein the group III nitride based compound semiconductor crystal is grown while the flux mixture and the group III element are mixed under stirring.

In the present invention, mixing treatment may be performed through physical movement (e.g., swinging, rocking, or rotation) of a reaction container, or may be performed by stirring the flux mixture with, for example, a stirring bar or a stirring blade. Alternatively, mixing treatment may be performed through thermal convection of the flux mixture by means of a heat gradient generated in the flux mixture by, for example, heating means. That is, in the present invention, mixing treatment may be performed through any of the aforementioned processes. These processes may be performed in any appropriate combination.

In a second aspect of the present invention, there is provided a method for producing a semiconductor crystal, the method comprising reacting nitrogen (N) with gallium (Ga), aluminum (Al), or indium (In), which are group III elements, in a flux mixture containing a plurality of metal elements selected from among alkali metals and alkaline earth metals, to thereby grow a group III nitride based compound semiconductor crystal, wherein at least a portion of a base substrate on which the group III nitride based compound semiconductor crystal is grown is formed of a material which can be dissolved in the flux mixture (hereinafter the material may be referred to as a “flux-soluble material”); and the flux-soluble material is dissolved in the flux mixture, at a temperature near the growth temperature of the group III nitride based compound semiconductor crystal, during the course of growth of the semiconductor crystal or after completion of growth of the semiconductor crystal.

Examples of the flux-soluble material which may be employed include, but are not necessarily limited to, silicon (Si).

A protective film may be formed on an exposed surface of the aforementioned flux-soluble material so that the thickness or formation pattern of the protective film arbitrarily controls the time when the flux-soluble material is dissolved in the flux mixture or the dissolution rate of the flux-soluble material. Examples of the material for forming such a protective film include aluminum nitride (AlN) and tantalum (Ta). Such a protective film may be formed through any well-known technique, such as crystal growth, vacuum deposition, or sputtering.

In a third aspect of the present invention, which is drawn to a specific embodiment of the second aspect, at least a portion of the aforementioned flux-soluble material contains an impurity to be added to the group III nitride based compound semiconductor crystal.

The entirety of the flux-soluble material may be formed solely of such a necessary impurity.

In a fourth aspect of the present invention, which is drawn to a specific embodiment of the second or third aspect, the group III nitride based compound semiconductor crystal is grown while the aforementioned flux mixture and the group III element are mixed under stirring.

In this case, mixing treatment may be performed through any of the aforementioned processes.

In a fifth aspect of the present invention, which is drawn to a specific embodiment of any one of the first to fourth aspects, the aforementioned flux mixture contains sodium (Na), and lithium (Li) or calcium (Ca).

That is, the flux mixture, which contains Na as the primary component, contains either lithium (Li) or calcium (Ca) as the secondary component.

In a sixth aspect of the present invention, which is drawn to a specific embodiment of any one of the first to fifth aspects, before growth of the group III nitride based compound semiconductor crystal, the crystal growth surface of the base substrate or seed crystal is subjected to cleaning treatment at a temperature of 900° C. to 1,100° C. for one minute or more by using, as a cleaning gas, hydrogen (H₂) gas, nitrogen (N₂) gas, ammonia (NH₃) gas, a rare gas (He, Ne, Ar, Kr, Xe, or Rn), or a gas mixture obtained by mixing, in arbitrary proportions, two or more gases selected from among these gases.

Preferably, this cleaning treatment is performed for two minutes to 10 minutes.

In a seventh aspect of the present invention, which is drawn to a specific embodiment of any one of the first to sixth aspects, the aforementioned flux mixture contains, as an impurity to be added to the group III nitride based compound semiconductor crystal, boron (B), thallium (Tl), calcium (Ca), a Ca-containing compound, silicon (Si), sulfur (S), selenium (Se), tellurium (Te), carbon (C), oxygen (O), aluminum (Al), indium (In), alumina (Al₂O₃), indium nitride (InN), silicon nitride (Si₃ N₄), silicon oxide (SiO₂), indium oxide (In₂O₃), zinc (Zn), iron (Fe), magnesium (Mg), zinc oxide (ZnO), magnesium oxide (MgO), or germanium (Ge).

The flux mixture may contain only one of these impurities, or a plurality thereof. One or a combination of these impurities may be chosen arbitrarily.

In an eighth aspect of the present invention, there is provided a semiconductor substrate, the substrate being produced through a method for producing a group III nitride based compound semiconductor crystal as recited in any one of the first to seventh aspects of the present invention, which substrate has a surface dislocation density of 1×10⁵ cm⁻² or less, and a maximum size of 1 cm or more.

The lower the dislocation density, the more preferred the substrate, and the greater the maximum size, the more preferred the substrate. From the viewpoint of industrial utility, the semiconductor substrate particularly preferably assumes, for example, a circular shape having a diameter of about 45 mm, a square shape having a size of about 27 mm×about 27 mm, or a square shape having a size of about 12 mm×about 12 mm.

In a ninth aspect of the present invention, which is drawn to a specific embodiment of the eighth aspect, the aforementioned semiconductor substrate has a thickness of 300 m or more.

The thickness of the semiconductor substrate is preferably 400 μm or more, more preferably about 400 μm to about 600 μm.

In a tenth aspect of the present invention, which is drawn to a specific embodiment of the eighth or ninth aspect, the aforementioned semiconductor substrate contains lithium (Li) at a volume density of 1×10¹⁷ cm⁻³ or less.

In a eleventh aspect of the present invention, which is drawn to a specific embodiment of any one of the eighth to tenth aspects, the aforementioned semiconductor substrate has a root mean square surface roughness, obtained from variations in height determined at a plurality of sites on the surface of the substrate with respect to a height-mean surface of the substrate serving as a reference surface, of 3.0 nm or less. The root mean square surface roughness is preferably 1.0 nm or less, more preferably 0.3 nm or less.

In a twelfth aspect of the present invention, which is drawn to a specific embodiment of any one of the eighth to eleventh aspects, the surface of the substrate has a curvature radius of 50 cm or more. The curvature radius is preferably 1 m or more, more preferably 2 m or more, most preferably 4 m or more.

In a thirteenth aspect of the present invention, which is drawn to a specific embodiment of any one of the eighth to twelfth aspects, the transmittance is 0.20 or more with respect to blue light having a wavelength of 460 nm which is incident in a direction vertical to the semiconductor substrate. The transmittance is preferably 0.40 or more, more preferably 0.60 or more.

In a fourteenth aspect of the present invention, which is drawn to a specific embodiment of any one of the eighth to thirteenth aspects, the transmittance is 0.10 or more with respect to bluish purple light having a wavelength of 380 nm which is incident in a direction vertical to the semiconductor substrate. The transmittance is preferably 0.30 or more, more preferably 0.50 or more.

In a fifteenth aspect of the present invention, which is drawn to a specific embodiment of any one of the eighth to fourteenth aspects, the electrical conductivity with respect to the direction vertical to the semiconductor substrate is 25 Ω⁻¹ cm⁻¹ or more. The electrical conductivity is preferably 50 Ω⁻¹ cm⁻¹ or more, more preferably 80 Ω⁻¹ cm⁻¹ or more.

In a sixteenth aspect of the present invention, which is drawn to a specific embodiment of any one of the eighth to fifteenth aspects, the thermal conductivity with respect to the direction vertical to the semiconductor substrate is 0.6 W/cm° C. or more. The thermal conductivity is preferably 0.9 W/cm° C. or more, more preferably 1.3 W/cm° C. or more.

In a seventeenth aspect of the present invention, which is drawn to a specific embodiment of any one of the eighth to sixteenth aspects, the half width of the XRD peak of the X-ray reflected by a (002) plane is 500 arc.sec. or less. The half width of the XRD peak is preferably 1.50 arc.sec. or less, more preferably 50 arc.sec. or less.

In a eighteenth aspect of the present invention, which is drawn to a specific embodiment of any one of the eighth to seventeenth aspects, the half width of the XRD peak of the X-ray reflected by a (100) plane is 500 arc.sec. or less. The half width of the XRD peak is preferably 100 arc.sec. or less, more preferably 30 arc.sec. or less.

In a nineteenth aspect of the present invention, the method for producing a group III nitride based compound semiconductor crystal through crystal growth of a group III nitride based compound semiconductor comprises employing a semiconductor substrate as recited in any one of specific embodiments of the eighth to eighteenth aspects.

In a twentieth aspect of the present invention, which is drawn to the nineteenth aspect, a group III nitride based compound semiconductor crystal formed of InₓAl_{y}Ga_{1-x-y}N (0≦x≦1, 0≦y≦1, 0≦x+y≦1) is grown through MOVPE.

In a twenty first aspect of the present invention, a semiconductor substrate formed of a group III nitride based compound semiconductor crystal produced through a method for producing a group III nitride based compound semiconductor crystal according to the nineteenth aspect or twentieth aspect, has a surface dislocation density of 1×10⁵ cm⁻² or less and a maximum size of 1 cm or more.

In a twenty second aspect of the present invention, which is drawn to the twentieth aspects, a semiconductor crystal layer formed of an aluminum-containing group III nitride based compound semiconductor (InₓAl_{y}Ga_{1-x-y}N (0≦x<1, 0<y≦1, 0<x+y≦1) to which an acceptor impurity element has been added is stacked through crystal growth treatment employing a gas mixture of hydrogen (H₂) and nitrogen (N₂) which has a relative nitrogen partial pressure of 40% to 80% and which serves as a carrier.

In the twenty-second aspect of the present invention, the relative nitrogen partial pressure is more preferably 50 to 75%, much more preferably 60 to 70%. The aforementioned aluminum-and-acceptor-impurity-containing semiconductor crystal layer is not necessarily provided directly on the crystal growth substrate. An optional semiconductor layer may be provided between the semiconductor crystal layer and the crystal growth substrate through, for example, additional crystal growth treatment. No particular limitation is imposed on the crystal growth conditions (e.g., the aforementioned relative nitrogen partial pressure) for providing such a semiconductor layer.

The above-described means of the present invention can effectively or reasonably solve the aforementioned problems.

### EFFECTS OF THE INVENTION

Effects obtained by the above-described aspects of the present invention are as follows.

Specifically, according to any one of the first to seventh aspects of the present invention, a semiconductor crystal of high quality can be efficiently produced through the flux process at low cost. Therefore, a semiconductor substrate according to any one of the eighth to eighteenth aspect of the present invention can be efficiently produced on a practical production level in high quality.

Particularly according to the first aspect of the present invention, the rate of dissolution of nitrogen in a flux mixture is effectively increased through mixing under stirring, and crystal materials are uniformly distributed in the flux mixture. In addition, such a suitable flux can be always uniformly supplied to a crystal growth surface. Therefore, according to the first aspect of the present invention, there can be produced a transparent semiconductor substrate of high quality, the substrate having low dislocation density and an almost flat crystal growth surface. Since high crystal growth rate and yield are achieved by the aforementioned effects, a bulk-form semiconductor substrate of high quality can be readily produced through crystal growth as desired.

According to the second aspect of the present invention, during the course of growth of a semiconductor crystal or after completion of growth of the semiconductor crystal, a flux-soluble material is dissolved in a flux mixture at a temperature near the growth temperature of the semiconductor crystal. Thus, when a target semiconductor crystal is removed from a reaction chamber, stress—which would otherwise occur due to, for example, a decrease in temperature upon removal of the semiconductor crystal from the reaction chamber—is not applied between the semiconductor crystal and a base substrate. Therefore, according to the second aspect of the present invention, the crack density of the target semiconductor crystal can be considerably reduced as compared with conventional semiconductor crystal.

The aforementioned flux-soluble material employed may be a relatively inexpensive material such as silicon (Si) Therefore, production cost can be reduced as compared with a conventional technique employing a GaN single-crystal free-standing substrate as a base substrate.

According to the third aspect of the present invention, when dissolution of the aforementioned flux-soluble material in the flux mixture is employed as a technique for addition of an impurity, addition of an impurity does not require any other technique. Furthermore, the amount of required impurity material can be saved.

According to the fourth aspect of the present invention, effects similar to those obtained in the first aspect by mixing with stirring can be obtained in the second or third aspect.

According to the fifth aspect of the present invention, yield or growth rate of a semiconductor crystal can be suitably or optimally regulated by the mixing ratio of lithium (Li) or calcium (Ca) in a flux mixture, and thus productivity of a target semiconductor crystal can be suitably or optimally regulated.

According to the sixth aspect of the present invention, foreign substances or impurities are successfully removed from a crystal growth surface on which a semiconductor crystal is to be grown, and therefore a target semiconductor crystal can be produced in higher quality.

According to the seventh aspect of the present invention, the semiconductor crystal having intended electrical conductivity or band gap can be produced.

According to the eighth aspect of the present invention, a semiconductor substrate useful for a semiconductor wafer for light-emitting devices (LEDs, LDs), photoreceptors, or electronic devices such as field-effect transistors, as well as useful for a substrate for producing these devices, can be fabricated so as to have a satisfactory quality on a practical level.

According to the ninth aspect of the present invention, a semiconductor substrate useful for a semiconductor wafer for light-emitting devices (LEDs, LDs), photoreceptors, or electronic devices such as field-effect transistors, as well as useful for a substrate for producing these devices, can be fabricated so as to have a satisfactory thickness on a practical level.

According to the tenth aspect of the present invention, a semiconductor substrate from which lithium (Li) atoms are removed as thoroughly as possible can be fabricated. Li is an impurity element which may inhibit p-type activation of a semiconductor crystal when a p-type impurity element is added to the semiconductor crystal.

According to the eleventh aspect of the present invention, there can be fabricated a high-quality semiconductor substrate including a flat crystal layer interface formed from crystal growth surfaces. Thus, such a semiconductor substrate is advantageous in formation of a flat crystal layer interface and growth of a high-quality semiconductor crystal layer on the substrate.

The twelfth aspect of the present invention provides an advantage in reduction of warpage-originating internal stress of a semiconductor substrate or a semiconductor crystal layer. Such a semiconductor crystal layer having small internal stress is advantageous from the viewpoint of prevention of dislocation.

According to the thirteenth or fourteenth aspect of the present invention, there can be fabricated a semiconductor substrate exhibiting excellent transmittance with respect to the light of interest. Such a semiconductor substrate is advantageous in enhancement of outside quantum efficiency relating to operation efficiency of devices such as LEDs.

According to the fifteenth aspect of the present invention, a substrate having high electrical conductivity can be fabricated. Such a substrate is advantageous in reduction of driving voltage of devices fabricated therefrom.

According to the sixteenth aspect of the present invention, a substrate having high thermal conductivity can be fabricated. Such a substrate is advantageous in enhancement of heat radiation of devices fabricated therefrom.

According to the seventeenth or eighteenth aspect of the present invention, there can be fabricated a semiconductor substrate for an optical device, which substrate prevents light scattering in the substrate which would otherwise be caused by, for example, dislocations in the semiconductor substrate.

According to the nineteenth aspect of the present invention, a high-quality semiconductor substrate is employed as a crystal growth substrate. Therefore, a high-quality semiconductor crystal can be grown on the substrate.

Particularly when the production method is carried but according to the twentieth aspect of the present invention employing a high-quality, semiconductor substrate, a plurality of or a large number of semiconductor crystal layers can be stacked on the substrate at high efficiency and low cost.

According to the twenty-first aspect of the present invention, a semiconductor substrate and a semiconductor crystal layer for forming a high-quality semiconductor wafer or device of interest can be effectively produced.

According to the twenty-second aspect of the present invention, carrier mobility and photoluminescence intensity of the aforementioned semiconductor crystal layer formed of a group III nitride based compound semiconductor containing an acceptor impurity element and aluminum can be enhanced. In addition, surface roughness of the semiconductor crystal layer can be reduced, and variation in aluminum composition and in thickness of the semiconductor crystal layer can be reduced. This is because crystal quality of the aluminum-containing group III nitride based compound semiconductor layer is improved through optimization of the nitrogen content of a carrier gas, and thus flat surface morphology is attained. Conceivably, these effects could be due to suppression of occurrence of defects or surface roughening which would otherwise be caused by re-evaporation of atoms from an epitaxially grown crystal.

Through stacking of these semiconductor crystal layers, any optical devices, such as a light-emitting diode (LED), a laser diode (LD), and a photocoupler, can be effectively fabricated.

### BRIEF DESCRIPTION OF THE DRAWINGS

FIG. 1 is a cross-sectional view showing a crystal growth apparatus employed in a first embodiment.

FIG. 2-A is a cross-sectional view showing operation of the crystal growth apparatus employed in Embodiment 1.

FIG. 2-B is a cross-sectional view showing operation of the crystal growth apparatus employed in Embodiment 1.

FIG. 2-C is a cross-sectional view showing operation of the crystal growth apparatus employed in Embodiment 1.

FIG. 3 is a cross-sectional view showing a template 10 prepared in Embodiment 2.

FIG. 4-A shows the configuration of a crystal growth apparatus employed in Embodiment 2.

FIG. 4-B is a partial cross-sectional view showing the crystal growth apparatus employed in Embodiment 2.

FIG. 5-A is a cross-sectional view showing a semiconductor crystal grown in Embodiment 2.

FIG. 5-B is a cross-sectional view showing the semiconductor crystal grown in Embodiment 2.

FIG. 5-C is a cross-sectional view showing the semiconductor crystal grown in Embodiment 2.

FIG. 6 is a cross-sectional view showing the LED 100.

### DESCRIPTION OF REFERENCE NUMERALS

2: Reaction chamber
3: Reaction container
8: Seed crystal
9: Flux mixture
H: Heater
10: Template
20: Semiconductor substrate
100: LED
101: Semiconductor substrate
107: p-type AlGaN layer

### BEST MODES FOR CARRYING OUT THE INVENTION

In the second aspect of the present invention, the aforementioned film formation pattern may be formed on an exposed surface of the flux-soluble material through any well-known technique, such as photolithography or etching. The smaller the thickness of a protective film formed on the exposed surface, the earlier the aforementioned dissolution time. The greater the area of a portion of the flux-soluble material exposed to the flux mixture, the higher the aforementioned dissolution rate. Dissolution of the flux-soluble material in the flux mixture starts at the time when the exposed portion of the flux-soluble material comes into contact with the flux mixture of high temperature, and the dissolution rate is almost proportional to the area of the exposed portion. Therefore, the time at which dissolution of the flux-soluble material starts, the time required for dissolution of the flux-soluble material, the dissolution rate, etc. can be arbitrarily controlled by appropriately determining the thickness of the protective film and the area of the exposed portion of the flux-soluble material. The time required for dissolution of the flux-soluble material may be regulated by varying, for example, the type or thickness of the flux-soluble material, or the temperature of the flux mixture.

No particular limitation is imposed on the method for producing a seed crystal or base substrate employed for the aforementioned crystal growth through the flux process, and the seed crystal or base substrate is effectively produced through, for example, the flux process, HVPE, MOVPE, or MBE. No particular limitation is imposed on the size or thickness of the seed crystal or base substrate, but, from the viewpoint of industrial utility, the seed crystal or base substrate preferably assumes, for example, a circular shape having a diameter of about 50 mm to about 150 mm, a square shape having a size of about 27 mm×about 27 mm, or a square shape having a size of about 12 mm×about 12 mm. Preferably, the seed crystal or base substrate has a crystal growth surface with a large curvature radius.

Preferably, the seed crystal or base substrate has a low dislocation density. However, in the case where the method according to any of the second to fourth aspects of the present invention is employed, the seed crystal or base substrate is not necessarily required to have a low dislocation density. It should be noted that, in this case, when the dislocation density is excessively low, the aforementioned flux-soluble material (base substrate) may be difficult to dissolve in the flux mixture.

No particular limitation is imposed on the crystal growth apparatus employed, so long as the flux process can be carried out by means of the apparatus. For example, a crystal growth apparatus described in any of Patent Documents 1 to 5 or modified apparatus thereof may be employed. When crystal growth is performed through the flux process, preferably, the temperature of a reaction chamber of a crystal growth apparatus employed can be arbitrarily raised or lowered to about 1,000° C. Preferably, the pressure of the reaction chamber can be arbitrarily increased or decreased to about 100 atm (about 1.0×10⁷ Pa). The electric furnace, reaction container, raw material gas tank, piping, etc. of a crystal growth apparatus employed are preferably formed of, for example, a stainless steel (SUS) material, an alumina material, or copper.

Specific embodiments of the present invention will next be described.

However, the present invention is not limited to the below-described embodiments.

### EMBODIMENT 1

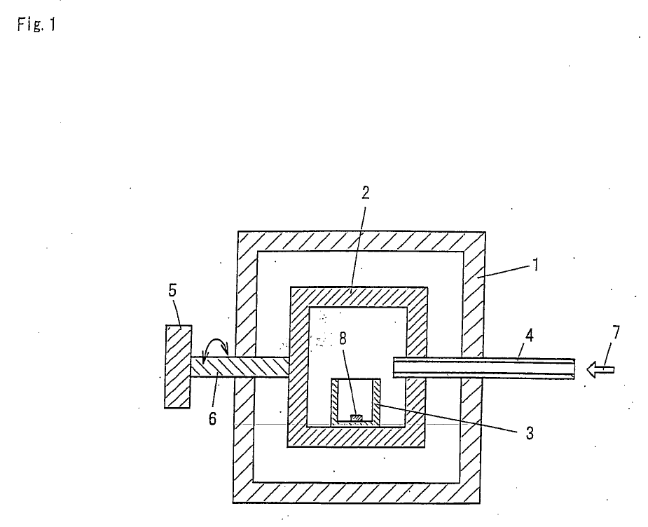

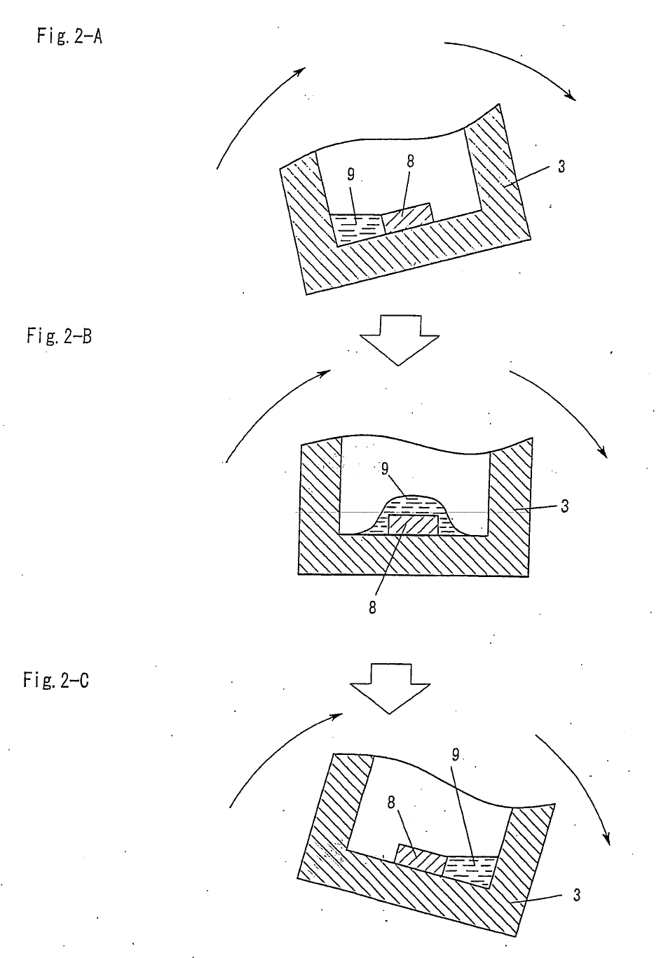

FIG. 1 is a cross-sectional view showing a crystal growth apparatus employed in Embodiment 1.

### 1. Crystal Growth Apparatus

This crystal growth apparatus is employed for growing a target semiconductor crystal on the crystal growth surface of a substrate 8 through the flux process. A heating container 2 provided in the interior of a heat-resistant, pressure-resistant container 1 is connected to a gas feed pipe 4 for feeding a nitrogen-containing gas 7. A shaft 6 extending from a swinging apparatus 5 is connected to the heating container 2 on the side opposite the gas feed pipe 4 such that the shaft 6 is coaxial with the gas feed pipe 4. The swinging apparatus 5 includes, for example, a motor and a motor controller. A flux mixture and the aforementioned substrate 8 are placed in a reaction container 3 formed of boron nitride.

### 2. Crystal Growth Through the Flux Process

Next will be described growth of a gallium nitride single crystal by means of the crystal growth apparatus shown in FIG. 1.

(1) Firstly, a GaN film (thickness: 3 μm) was formed on the crystal growth surface of a sapphire substrate through MOVPE, to thereby yield the substrate 8 shown in FIG. 1.

(2) Subsequently, the substrate 8 was placed on the bottom of the reaction container 3, and then sodium (Na) (about 8.8 g) and lithium (Li) (about 0.027 g) were placed in the reaction container 3. The ratio by mole of Na to Li is 99:1.

(3) Subsequently, the reaction container 3 was placed in the heating container 2, and the reaction container 3 was inclined in a predetermined direction so that the substrate 8 did not come into contact with a flux mixture of sodium (Na) and lithium (Li).

(4) Subsequently, nitrogen gas (N₂) heated to about 1,000° C. was fed into the reaction chamber for about 30 minutes, to thereby clean the crystal growth surface of the substrate 8. During this cleaning, the gas pressure in the heating container 2 was periodically varied within a range of 0 to 10 atm (1 to 10×10⁵ Pa) or thereabouts so that nitrogen (N₂) gas was fed (compressed) into and discharged from the heating container 2 in a repeated manner, to thereby perform influx/discharge of the cleaning gas.

(5) Thereafter, nitrogen gas was newly fed into the heating container 2; the gas pressure in the container was increased to 10 atm (about 10×10⁵ Pa); and the temperature of the container was adjusted at 890° C.

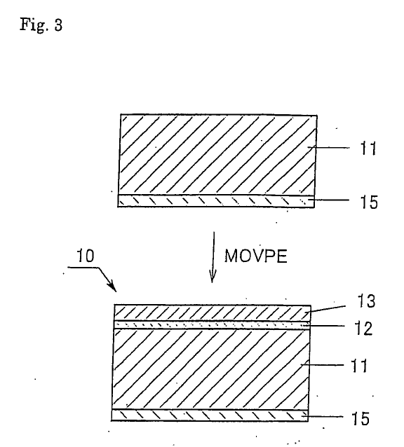

(6) Thereafter, as shown in FIGS. 2-A, 2-B, and 2-C, a liquid raw material (flux mixture) 9 was moved from side to side by swinging the reaction container 3 by means of the swinging apparatus 5, so that the crystal growth surface of the GaN film was always thinly covered with the flux mixture 9. While this swinging was continued, the aforementioned temperature and pressure were maintained constant for four hours. In this case, swinging may be performed so that the flux is reciprocated once to several times per minute.

(7) Thereafter, while the reaction container 3 was inclined so that the flux mixture did not come into contact with the substrate 8, the aforementioned temperature and pressure were lowered to about ambient temperature and ambient pressure, respectively, and then the substrate 8 was removed from the heating container 2. Subsequently, the flux mixture (Na and Li) deposited onto the periphery of the substrate 8 was removed with ethanol, to thereby yield a transparent GaN single crystal in bulk form grown on the substrate 8 and having a uniform thickness.

Thereafter, the sapphire substrate is removed through, for example, polishing or a laser lift-off technique.

The GaN single crystal produced through the above-described method was found to have a thickness of about 10 μm and a maximum size of 5 cm or more.

Photoluminescence intensity of the GaN single crystal was measured at ambient temperature, and was found to be 10 mW or more with respect to excitation light of 325 nm.

The half width of an XRD peak attributed to an X-ray reflected by a (100) plane was found to be 100 arc.sec. or less.

These data show that when, for example, the above-described crystal growth process is carried out for about 160 hours, there can be produced a transparent semiconductor substrate of high quality for fabricating an electronic device or an optical device, the substrate having a thickness of 400 μm and a low dislocation density.

In the above-described crystal growth process, the secondary component of the flux mixture is lithium (Li) However, the secondary component of the flux mixture may be calcium (Ca) in place of lithium (Li). Alternatively, lithium (Li) may be employed together with calcium (Ca).

When an impurity; for example, boron (B), thallium (TI), calcium (Ca), a Ca-containing compound, silicon (Si), sulfur (S), selenium (Se), tellurium (Te), carbon (C), oxygen (O), aluminum (Al), indium (In), alumina (Al₂O₃), indium nitride (InN), silicon nitride (Si₃N₄), silicon oxide (SiO₂), indium oxide (In₂O₃), zinc (Zn), iron (Fe), magnesium (Mg), zinc oxide (ZnO), magnesium oxide (MgO), or germanium (Ge), is added to the aforementioned flux mixture, a target GaN single crystal can be doped with such an impurity. Through such a doping technique, a target semiconductor substrate for an electronic device or an optical device can be provided with electrical conductivity or semi-insulating property.

The nitrogen (N)-containing gas, which is a raw material for forming the crystals, may be, for example, nitrogen gas (N₂), ammonia gas (NH₃), or a mixture of these gases. In a group III nitride based compound semiconductor represented by the aforementioned compositional formula, which constitutes a target semiconductor crystal, at least a portion of the aforementioned group III element (Al, Ga, or In) atoms may be substituted by, for example, boron (B) or thallium (Tl); or at least a portion of nitrogen (N) atoms may be substituted by, for example, phosphorus (P), arsenic (As), antimony (Sb), or bismuth (Bi).

A p-type impurity (acceptor) added may be, for example, an alkaline earth metal (e.g., magnesium (Mg) or calcium (Ca)). An n-type impurity (donor) added may be, for example, silicon (Si), sulfur (S), selenium (Se), tellurium (Te), or germanium (Ge). Two or more impurity (acceptor or donor) elements may be added in a single step, or both p-type and n-type impurities may be added in a single step. Such an impurity can be added to a target semiconductor crystal by, for example, dissolving the impurity in the flux mixture in advance.

### EMBODIMENT 2

Next will be described, with reference to FIG. 3, a procedure for preparing a base substrate (template 10) employed in the crystal growth step of the flux process in Embodiment 2.

### 1. Preparation of Base Substrate

(1) Firstly, a protective film 15 is formed on the back surface of a silicon substrate 11 (flux-soluble material). The protective film 15 may be formed by providing an AlN layer on the substrate through MOVPE or a similar technique. Alternatively, the protective film 15 may be formed of an appropriate metal such as tantalum (Ta) by means of a sputtering apparatus or a vacuum deposition apparatus.

(2) Subsequently, through crystal growth by MOVPE, an AlGaN buffer layer 12 (thickness: about 4 μm) is formed on the silicon substrate 11 (thickness: about 400 μm), and a GaN layer 13 is formed on the buffer layer 12. The GaN layer 13 can happen to be dissolved in a flux to some extent by the time when growth of a target semiconductor crystal is initiated in the flux process. Therefore, the GaN layer 13 is formed to have such a thickness that it is not completely dissolved in the flux mixture until crystal growth is initiated.

The template 10 (base substrate) can be prepared through the above-described steps (1) and (2)

### 2. Configuration of Crystal Growth Apparatus

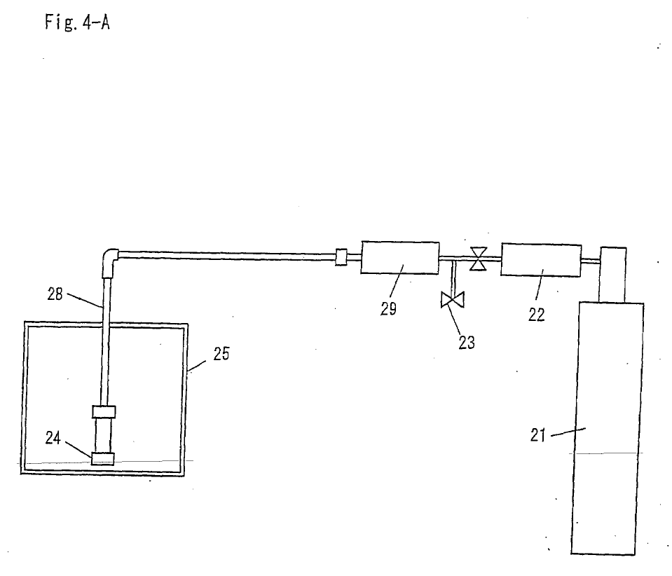

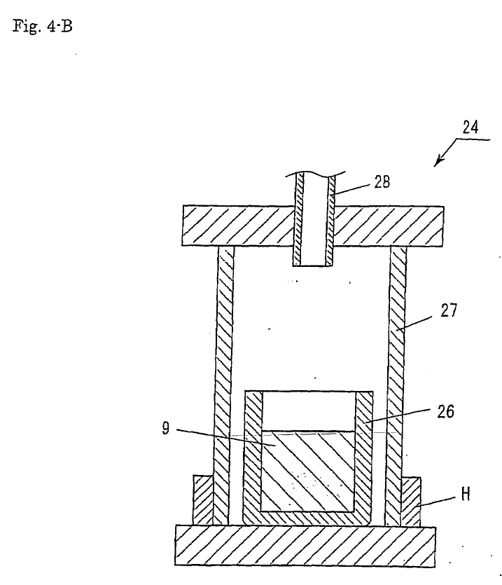

FIGS. 4-A and 4-B show the configuration of a crystal growth apparatus employed in Embodiment 2. The crystal growth apparatus includes a raw material gas tank 21 for supplying nitrogen gas; a pressure regulator 22 for regulating the pressure of a crystal growth atmosphere; a leakage valve 23; and an electric furnace 25 for performing crystal growth. The electric furnace 25, the pipe for connecting the raw material gas tank 21 to the electric furnace 25, etc. are formed of, for example, a stainless steel (SUS) material, an alumina material, or copper.

The electric furnace 25 includes a stainless steel container 24 (reaction chamber) therein, and the stainless steel container 24 includes a crucible 26 (reaction container) therein. The crucible 26 may be formed of, for example, boron nitride (BN) or alumina (Al₂O₃).

The temperature of the interior of the electric furnace 25 can be arbitrarily raised or lowered within a range of 1,000° C. or lower. The crystal growth pressure of the interior of the stainless steel container 24 can be arbitrarily increased or decreased within a range of 1.0×10⁷ Pa or less by means of, for example, the pressure regulator 22 or 29 or the leakage valve 23 via a pipe 28.

FIG. 4-B is a cross-sectional view showing the stainless steel container 24. The reaction chamber is defined by a cylindrical side wall 27, and a ring-shaped heater H is provided on an outer bottom portion of the side wall 27. The heater H is provided for heating the crucible 26 (reaction container) via the bottom of the reaction chamber, to thereby cause thermal convection to occur in a flux mixture 9 contained in the crucible 26.

### 3. Crystal Growth Step

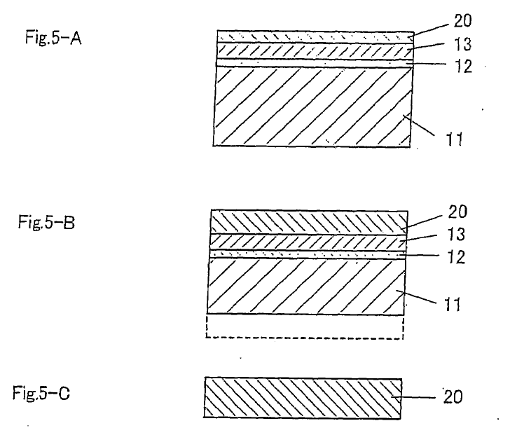

Next will be described, with reference to FIGS. 5-A to 5-C, the crystal growth step in the present embodiment by means of the crystal growth apparatus shown in FIGS. 4-A and 4-B.

(1) Firstly, sodium (Na), lithium (Li), and Ga (i.e., a group III element) are placed in the reaction container (crucible 26), and the reaction container (crucible 26) is placed in the reaction chamber (stainless steel container 24) of the crystal growth apparatus, followed by evacuation of the gas contained in the reaction chamber. The ratio by mole of sodium (Na) to lithium (Li) was 99:1. If necessary, any of the aforementioned additives (e.g., an alkaline earth metal) may be added to the crucible in advance. Setting of the substrate or the raw material in the reaction container is carried out in a glove box filled with an inert gas (e.g., Ar gas), since, when such an operation is performed in air, Na is immediately oxidized.

(2) Subsequently, the gas pressure in the reaction chamber is periodically varied within a range of 1 to 10 atm (1 to about 1×10⁵ Pa) or thereabouts so that nitrogen (N₂) gas is fed (compressed) into and discharged from the reaction chamber in a repeated manner, to thereby clean the crystal growth surface of the substrate. This cleaning is performed at 900° C. for about 30 minutes.

(3) Subsequently, while the temperature of the crucible is regulated to 850° C. to 880° C., nitrogen gas (N₂) is newly fed into the reaction chamber of the crystal growth apparatus, and the gas pressure in the reaction chamber is maintained at to 50 atm (1 to 5×10⁶ Pa) or thereabouts. In this case, the protective film 15 of the above-prepared template 10 is immersed in a melt (flux mixture) formed through the above temperature rising, and the crystal growth surface of the template 10 (i.e., the exposed surface of the GaN layer 13) is located in the vicinity of the interface between the melt and the nitrogen gas. The template 10 may be installed on the bottom of the crucible 26.

(4) Thereafter, thermal convection is generated in the flux mixture 9 by means of heat from the heater H shown in FIG. 4-B, whereby the crystal growth conditions described above in (3) are continuously maintained while the flux mixture is stirred.

Under the above-described conditions, the elements constituting the material for a group III nitride based compound semiconductor are continuously in a supersaturated state in the vicinity of the interface between a Ga—Na melt and the nitrogen gas. Therefore, as shown in FIG. 5-A, a target semiconductor crystal (n-type GaN single crystal 20) can be successfully grown on the crystal growth surface of the template 10 (FIG. 3). The reason why the n-type electrically conductive semiconductor crystal (n-type GaN single crystal 20) is obtained is that Si, which constitutes the silicon substrate 11 dissolved in the flux mixture, is added as an n-type additive to the crystal during growth thereof (FIG. 5-B).

The protective film 15 may be formed to have a large thickness so that the silicon substrate 11 is not dissolved in the flux mixture during the crystal growth step. In this case, there can be formed a semi-insulating electronic-device-forming semiconductor substrate or optical device substrate which is not doped with silicon (Si)

### 4. Dissolution of Crystal Growth Substrate

After the n-type GaN single crystal 20 is grown to have a sufficient thickness (e.g., about 500 m or more) through the above-described crystal growth step, the temperature of the crucible is continued to be maintained at 850° C. to 880° C. until the protective film 15 and the silicon substrate 11 are completely dissolved in the flux mixture (FIGS. 5-B and 5-C) Thereafter, while the pressure of the nitrogen gas (N₂) is maintained at 10 to 50 atm (1 to 5×10⁶ Pa) or thereabouts, the temperature of the reaction chamber is lowered to 100° C. or less.

The step of dissolving the silicon substrate 11 in the flux mixture and the above temperature lowering step may be carried out partially in parallel. Also, at least a portion of the protective film 15 or the silicon substrate 11 may be dissolved in the flux mixture as described above during growth of the GaN single crystal 20. The parallel/simultaneous mode in which these steps are carried out may be appropriately adapted for, for example, the formation of the protective film 15.

### 5. Removal of Flux

Subsequently, the above-grown n-type GaN single crystal (target semiconductor crystal) is removed from the reaction chamber of the crystal growth apparatus, and the single crystal is cooled to 30° C. or lower. Thereafter, while the temperature of an atmosphere surrounding the n-type GaN single crystal 20 is maintained at 30° C. or lower, the flux (Na) deposited on the periphery of the single crystal is removed by use of ethanol.

When the above-described steps are sequentially carried out, there can be produced, through the flux process and at low cost, a semiconductor substrate (n-type GaN single crystal 20) of high quality, which has a thickness of 400 μm or more and has considerably reduced cracks as compared with conventional semiconductor substrates.

### EXAMPLE 3

In Example 3, in order to determine crystal growth conditions for the growth of a portion (p-type layer 107) of the LED described hereinbelow, samples of the p-type AlGaN crystal layer were fabricated, and characteristics of these semiconductor layers were investigated.

The samples (p-type AlGaN crystal layer) were grown through MOCVD employing a gas mixture of hydrogen (H₂) and nitrogen (N₂) as a carrier gas, with the relative nitrogen partial pressure being varied from 0 to 1, to thereby produce the aforementioned stacked p-type AlGaN layer. A sapphire substrate was employed as a crystal growth substrate. The source gases employed in the growth were ammonia gas (NH₃), trimethylgallium (Ga(CH₃)₃), trimethylaluminum (Al(CH₃)₃), trimethylindium (In(CH₃)₃), silane (SiH₄), and cyclopentadienylmagnesium (Mg(C₅H₅)₂). Nitrogen (N₂) was fed to a bubbler for feeding metal source gases.

Each of the above samples (p-type AlGaN crystal layers) was produced through providing an Al_{0.24}Ga_{0.76}N:Mg layer on a stacked structure, which includes a sapphire substrate and deposited sequentially thereon an AlN buffer layer and an undoped GaN layer, and subjecting the obtained structure to resistance-lowering treatment under predetermined conditions. That is, the p-type AlGaN crystal layer of interest was doped with magnesium serving as an acceptor impurity element.

Table 1 shows semiconductor physical properties of the samples.

TABLE 1

| | Relative partial pressure R | | | | | | | | | | |
|---|---|---|---|---|---|---|---|---|---|---|---|
| | 0 | 0.2 | 0.4 | 0.5 | 0.55 | 0.6 | 0.65 | 0.7 | 0.75 | 0.8 | 1.0 |
| PL intensity | X | ◯ | ◯ | ◯ | ◯ | ◯ | ◯ | ◯ | Δ | Δ | Δ |
| Mobility | X | ◯ | ◯ | ◯ | ◯ | Δ | Δ | Δ | Δ | Δ | Δ |
| Surface | ◯ | ◯ | ◯ | ◯ | ◯ | ◯ | ◯ | ◯ | ◯ | ◯ | Δ |
| roughness | | | | | | | | | | | |
| Al | X | X | X | X | X | Δ | Δ | ◯ | ◯ | ◯ | Δ |
| proportion | | | | | | | | | | | |
| variation | | | | | | | | | | | |
| Thickness | X | X | Δ | ◯ | ◯ | ◯ | ◯ | ◯ | ◯ | ◯ | Δ |
| variation | | | | | | | | | | | |

As compared with the case where R = 1.0,
◯: improved,
Δ: comparable, and
X: impaired.

As used herein, the symbol “R” refers to the relative partial pressure of nitrogen in the aforementioned carrier gas. In Table 1, the symbol “O” corresponds to improvement of property as compared with the case where R=1.0; the symbol “Δ” corresponds to property comparable to that in the case where R=1.0; and the symbol “x” corresponds to impairment of property as compared with the case where R=1.0. Items for evaluation of the sample are as follows.

### (1) PL Intensity

Samples were compared in terms of photoluminescence intensity as measured at a wavelength of 326 nm. Higher photoluminescence intensity is preferred.

### (2) Mobility.

Samples were compared in terms of hole mobility. Higher hole mobility is preferred.

### (3) Surface Roughness

Samples were compared in terms of surface roughness. Smaller surface roughness—which is represented by a root mean square (r.m.s.) obtained from variations in height determined at a plurality of sites on the surface of the sample (p-type AlGaN crystal layer) with respect to a height-mean surface of the sample serving as a reference surface—is preferred.

### (4) Al Proportion Variation

Samples were compared in terms of variation in Al compositional proportion as measured at a plurality of sites of the sample. More uniform Al compositional proportion is preferred.

### (5) Thickness Variation

Samples were comparison in terms of variation in thickness as measured at a plurality of sites of the samples (p-type AlGaN crystal layer). More uniform thickness is preferred.

These evaluation data indicate that when a carrier gas containing nitrogen and hydrogen is employed, and the relative nitrogen partial pressure R is regulated to satisfy the relationship: 0.6≦R≦0.7, best properties are obtained.

Next will be described an example of production of an LED including a p-type AlGaN crystal layer formed under such conditions.

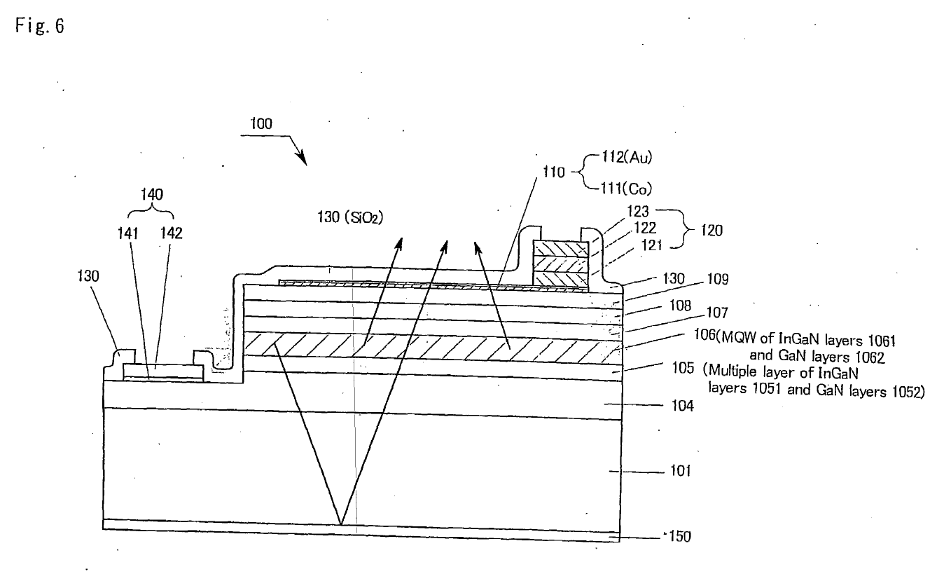

FIG. 6 is a schematic cross-sectional view showing the LED. The LED 100 includes a crystal growth substrate 101 with thickness of about 300 μm and an n-type contact layer 104 (high carrier concentration n⁺ layer) of GaN doped with silicon (Si) at 5×10¹⁸ cm⁻³ with thickness of about 3 μm thereon, the crystal growth substrate 101 being produced through the production method described above in Embodiment 2.

On the n-type contact layer 104 is formed a multiple layer 105 (thickness: 90 nm) including 20 layer units, each including an undoped In_{0.1}Ga_{0.9}N layer 1051 (thickness: 1.5 nm) and an undoped GaN layer 1052 (thickness: 3 nm), wherein the layers 1051 and the layers 1052 are alternatingly provided. On the multiple layer 105 is formed a multiple quantum well layer 106 including undoped GaN barrier layers 1062 (thickness: 17 nm each) and undoped In_{0.2}Ga_{0.8}N well layers 1061 (thickness: 3 nm each), wherein the layers 1062 and the layers 1061 are alternatingly provided.

On the multiple quantum well layer 106, a p-type layer 107 having a thickness of 15 nm was formed from p-type Al_{0.2}Ga_{0.8}N doped with Mg (2×10¹⁹/cm³). On the p-type layer 107, a layer 108 having a thickness of 300 nm was formed from undoped Al_{0.02}Ga_{0.98}N. On the layer 108, a p-type contact layer 109 having a thickness of 200 nm was formed from p-type GaN doped with Mg (1×10²⁰/cm³).

A transparent thin-film p electrode 110 is formed on the p-type contact layer 109 through metal vapor deposition, and an n electrode 140 is formed on the n-type contact layer 104. The transparent thin-film p electrode 110 includes a first layer 111 which is directly joined to the p-type contact layer 109 and which is formed of cobalt (Co) film having a thickness of about 1.5 nm, and a second layer 112 which is joined to the cobalt film and which is formed of gold (Au) film having a thickness of about 6 nm.

A thick-film p electrode 120 includes a first layer 121 formed of vanadium (V) film having a thickness of about 18 nm, a second layer 122 formed of gold (Au) film having a thickness of about 1.5 m, and a third layer 123 formed of aluminum (Al) film having a thickness of about 10 nm, the three layers being sequentially stacked on the transparent thin-film p electrode 110, with the first layer 121 being directly provided on the electrode 110.

The n electrode 140 of multi-layer structure, provided on a partially exposed area of the n-type contact layer 104, includes a first layer 141 formed of vanadium (V) film having a thickness of about 18 nm, and a second layer 142 formed of aluminum (Al) film having a thickness of about 100 nm.

The uppermost area of the semiconductor structure is covered with a protective film 130 formed of SiO₂ film, and the bottom surface of the GaN substrate 101; i.e., an outer bottommost area, is covered, through metal vapor deposition, with a reflecting metal layer 150 formed of aluminum (Al) film having a thickness of about 500 nm. Notably, the reflecting metal layer 150 may be formed of a metal such as Rh, Ti, or W, as well as a nitride such as TiN or HfN.

In the LED 100 having the aforementioned configuration, the p-type Al_{0.2}Ga_{0.8}; N layer 107 was formed by using, as a carrier gas for raw material gases, a gas mixture of nitrogen and hydrogen (relative nitrogen partial pressure R=2/3), and crystal growth for forming the other semiconductor crystal layers was performed by using, as a carrier gas for raw material gases, merely nitrogen (i.e., R=1.0). The LED 100 exhibited an emission intensity higher, by about 20%, than that of an LED product having the same configuration as described above but including a p-type layer 107 formed by using, as a carrier gas, merely nitrogen (i.e., R=1.0).

When such a group III nitride based compound semiconductor layer containing an acceptor impurity and aluminum, which is formed through optimization of relative nitrogen partial pressure R, is provided directly on a light-emitting layer of an LED or an LD, the semiconductor layer effectively acts as a large-band-gap layer on the light-emitting layer, etc. Another conceivable reason why the aluminum-containing group III nitride based compound semiconductor layer is formed in very high quality is that the substrate 101 employs a crystal growth substrate formed of a semiconductor crystal of excellent quality produced through the production method described above in Embodiment 2. Therefore, conceivably, about 20% enhancement of emission intensity of the LED 100 is due to the synergistic effect of high quality of the crystal growth substrate and optimization of crystal growth conditions (relative nitrogen partial pressure R).

### (Other Modifications)

The present invention is not limited to the above-described embodiments, and the below-exemplified modifications may be made. Effects of the present invention can also be obtained through such modifications or applications according to the operation of the present invention.

### (Modification 1)

In the aforementioned Embodiment 3, the multiple quantum well layer 106 is formed as a light-emitting layer. However, in an LED including a p-type AlGaN layer as described above in Embodiment 3, the light-emitting layer of the LED may have an arbitrary structure; for example, a single-layer structure, a single quantum well (SQW) structure, or a multiple quantum well (MQW) structure. Particularly when the light-emitting layer has a multiple quantum well structure, preferably, the light-emitting layer includes at least a well layer formed of an indium (In)-containing group III nitride based compound semiconductor Al_{y}Ga_{1-y-z}In_{z}N (0≦y<1, 0<z≦1) having appropriate compositional proportions.

Such a configuration including the aforementioned p-type AlGaN layer may be applied to another optical device (e.g., an LD).

### INDUSTRIAL APPLICABILITY

The present invention is useful for producing a semiconductor device from a group III nitride based compound semiconductor crystal. Examples of such a semiconductor device include, in addition to the aforementioned electronic devices, light-emitting devices (e.g., an LED and an LD), phororeceptors, and optoelectronic integrated circuits (OEICs) including such devices.

The transistor of the present invention may be a field-effect transistor or a bipolar transistor. Examples of field-effect transistors which can be produced according to the present invention include semiconductor devices such as MISFET, MOSFET, HFET, MODFET, JFET, HJFET, and HEMT; and power transistors for power control, such as power MOSFET and IGET.

1. A method for producing a group III nitride based compound semiconductor crystal, the method comprising reacting nitrogen (N) with gallium (Ga), aluminum (Al), or indium (In), which are group III elements, in a flux mixture containing a plurality of metal elements selected from among alkali metals and alkaline earth metals, to thereby grow a group III nitride based compound semiconductor crystal, wherein said group III nitride based compound semiconductor crystal is grown while the flux mixture and the group III element are mixed under stirring.

2. A method for producing a group III nitride based compound semiconductor crystal, the method comprising reacting nitrogen (N) with gallium (Ga), aluminum (Al), or indium (In), which are a group III element, in a flux mixture containing a plurality of metal elements selected from among alkali metals and alkaline earth metals, to thereby grow a group III nitride based compound semiconductor crystal, wherein at least a portion of a base substrate on which the group III nitride based compound semiconductor crystal is grown is formed of a flux-soluble material, and the flux-soluble material is dissolved in the flux mixture, at a temperature near the growth temperature of the group III nitride based compound semiconductor crystal, during the course of growth of the semiconductor crystal or after completion of growth of the semiconductor crystal.

3. A method for producing a group III nitride based compound semiconductor crystal according to claim 2, wherein at least a portion of the flux-soluble material contains an impurity to be added to the group III nitride based compound semiconductor crystal.

4. A method for producing a group III nitride based compound semiconductor crystal according to claim 2, wherein the group III nitride based compound semiconductor crystal is grown while the flux mixture and the group III element are mixed under stirring.

5. A method for producing a group III nitride based compound semiconductor crystal according to claim 1, wherein the flux mixture contains sodium (Na), and lithium (Li) or calcium (Ca).

6. A method for producing a group III nitride based compound semiconductor crystal according to claim 1, wherein, before growth of the group III nitride based compound semiconductor crystal, the crystal growth surface of the base substrate or seed crystal is subjected to cleaning treatment at a temperature of 900° C. to 1,100° C. for one minute or more by using, as a cleaning gas, hydrogen (H₂) gas, nitrogen (N₂) gas, ammonia (NH₃) gas, a rare gas (He, Ne, Ar, Kr, Xe, or Rn), or a gas mixture obtained by mixing, in arbitrary proportions, two or more gases selected from among these gases.

7. A method for producing a group III nitride based compound semiconductor crystal according to claim 1, wherein the flux mixture contains, as an impurity to be added to the group III nitride based compound semiconductor crystal, boron (B), thallium (TI), calcium (Ca), a Ca-containing compound, silicon (Si), sulfur (S), selenium (Se), tellurium (Te), carbon (C), oxygen (O), aluminum (Al), indium (In), alumina (Al₂O₃), indium nitride (InN), silicon nitride (Si₃N₄), silicon oxide (SiO₂), indium oxide (In₂O₃), zinc (Zn), iron (Fe), magnesium (Mg), zinc oxide (ZnO), magnesium oxide (MgO), or germanium (Ge).

8. A semiconductor substrate, characterized by being produced through a method for producing a group III nitride based compound semiconductor crystal as recited in claim 1, which substrate has a surface dislocation density of 1×10⁵ cm⁻² or less, and a maximum size of 1 cm or more.

9. A semiconductor substrate according to claim 8, which has a thickness of 300 μm or more.

10. A semiconductor substrate according to claim 8, which contains lithium (Li) at a volume density of 1×10¹⁷ cm⁻³ or less.

11. A semiconductor substrate according claim 8, which has a root mean square surface roughness, obtained from variations in height determined at a plurality of sites on the surface of the substrate with respect to a height-mean surface of the substrate serving as a reference surface, of 3.0 nm or less.

12. A semiconductor substrate according to claim 8, wherein a surface of the substrate has a radius of curvature of 50 cm or more.

13. A semiconductor substrate according to claim 8, which exhibits a transmittance, with respect to blue light having a wavelength of 460 nm and as determined in a direction vertical to the semiconductor substrate, of 0.20 or higher.

14. A semiconductor substrate according to claim 8, which exhibits a transmittance, with respect to bluish purple light having a wavelength of 380 nm and as determined in a direction vertical to the semiconductor substrate, of 0.10 or higher.

15. A semiconductor substrate according to claim 8, which has an electrical conductivity, as determined in a direction vertical to the semiconductor substrate, of 25 Ω⁻¹ cm⁻¹ or higher.

16. A semiconductor substrate according to claim 8, which has a thermal conductivity, as determined in a direction vertical to the semiconductor substrate, of 0.6 W/cm° C. or higher.

17. A semiconductor substrate according to claim 8, wherein an XRD peak attributed to an X-ray reflected by a (002) plane has a half width of 500 arc.sec. or less.

18. A semiconductor substrate according to claim 8, wherein an XRD peak attributed to an X-ray reflected by a (100) plane has a half width of 500 arc.sec. or less.

19. A method for producing a group III nitride based compound semiconductor crystal through crystal growth of a group III nitride based compound semiconductor, comprising employing a semiconductor substrate as recited in claim 8 as a crystal growth substrate.

20. A method for producing a group III nitride based compound semiconductor crystal according to claim 19, wherein a group III nitride based compound semiconductor crystal formed of InₓAl_{y}Ga_{1-x-y}N (0≦x1, 0≦y≦1, 0≦x+y≦1) is grown through MOVPE.

21. A semiconductor substrate formed of a group III nitride based compound semiconductor crystal produced through a method for producing a group III nitride based compound semiconductor crystal according to claim 19, wherein the semiconductor substrate has a surface dislocation density of 1×10⁵ cm⁻² or less and a maximum size of 1 cm or more.

22. A method for producing a group III nitride based compound semiconductor crystal according to claim 20, wherein a semiconductor crystal layer formed of an aluminum-containing group III nitride based compound semiconductor (InₓAl_{y}Ga_{1-x-y}N (0x<1, 0≦y≦1, 0<x+y≦1) to which an acceptor impurity element has been added is stacked through crystal growth treatment employing a gas mixture of hydrogen (H₂) and nitrogen (N₂) which has a relative nitrogen partial pressure of 40% to 80% and which serves as a carrier gas.
